(19) United States
(12) Patent Application Publication
(10) Pub. No.: US 2026/0082895 A1
(43) Pub. Date: Mar. 19, 2026

(54) CFET INTEGRATED CIRCUITS HAVING VERTICAL INTERCONNECTS IN SOME ROWS OF CIRCUIT CELLS

(71) Applicant: TAIWAN SEMICONDUCTOR MANUFACTURING COMPANY, LTD., Hsinchu (TW)

(72) Inventors: Wei-Cheng TZENG, Hsinchu (TW); Chun-Yen LIN, Hsinchu (TW); Wei-Cheng LIN, Hsinchu (TW); Jiann-Tyng TZENG, Hsinchu (TW)

(21) Appl. No.: 19/014,959

(22) Filed: Jan. 9, 2025

Related U.S. Application Data
(60) Provisional application No. 63/695,614, filed on Sep. 17, 2024.

(51) Int. Cl. H01L 23/528; H01L 21/768; H01L 23/522; H10D 84/85; H10D 89/10

(52) U.S. Cl. CPC H10W 20/427; H10D 84/856; H10D 89/10; H10W 20/056; H10W 20/42

(57) ABSTRACT

An integrated circuit device with CFET devices includes tall cells in a first row and short cells in a second row. The integrated circuit device further includes one or more self-aligned vertical interconnects in the first row of tall cells. Each self-aligned vertical interconnect is at least partially embedded into a side-recess. The side-recess has a boundary surface conformally coated with insulation materials which terminate at least one gate-conductor intersecting an active-region structure in a tall cell. In the integrated circuit device, at least three short cells consecutively arranged in the second row are absence of any self-aligned vertical interconnect.

### PRIORITY CLAIM

The present application claims the priority of U.S. Provisional Application No. 63/695,614, filed Sep. 17, 2024, which is incorporated herein by reference in its entirety.

### BACKGROUND

An integrated circuit (IC) typically includes a number of IC devices that are manufactured in accordance with one or more IC layout diagrams. IC devices sometimes include complementary field effect transistor (CFET) devices. A CFET device generally has an upper FET overlying a lower FET in a stacked configuration. Both the upper FET and the lower FET in a CFET device are positioned above the conductive lines in a lower conductor layer but below the conductive lines in an upper conductor layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a layout diagram of an integrated circuit having a self-aligned vertical interconnect implemented in a circuit cell which has an inverter circuit, in accordance with some embodiments.

FIGS. 2A-2C are cross-sectional views of an integrated circuit, in accordance with some embodiments.

FIGS. 3A-3C are schematics of a process flow for fabricating a self-aligned vertical interconnect embedded partially in a side-recess adjacent to active-region structures, in accordance with some embodiments.

FIG. 4 is a schematic of a simplified layout diagram of a circuit cell, in accordance with some embodiments.

FIG. 5A is a schematic of a simplified layout diagram of a portion of an integrated circuit, in accordance with some embodiments.

FIGS. 5B-5C are cross-sectional views of an integrated circuit in FIG. 5A, in accordance with some embodiments.

FIG. 6 is a schematic of a simplified layout diagram of a portion of an integrated circuit, in accordance with some embodiments.

FIGS. 7A-7C are schematics of simplified layout diagrams of a portion of an integrated circuit, in accordance with some embodiments.

FIG. 8 is a flowchart of a method of manufacturing an integrated circuit (IC) having CFET devices, in accordance with some embodiments.

FIG. 9 is a block diagram of an electronic design automation (EDA) system in accordance with some embodiments.

FIG. 10 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, an integrated circuit device with CFET devices includes tall cells in a first row and short cells in a second row. The integrated circuit device further includes one or more vertical interconnects in the first row of tall cells. Each vertical interconnect, which extends in a direction which is normal to the surface of the substrate, is at least partially embedded into a side-recess. The side-recess has a boundary surface conformally coated with insulation materials which terminate at least one gate-conductor intersecting an active-region structure in a tall cell. In some implementations, none of the short cells in the second row includes a vertical interconnect.

In some implementations, each of the vertical interconnects in the first row of tall cells directly connects an upper-layer conducting line with a lower-layer conducting line. The upper-layer conducting line is in an upper conductor layer above all transistors in the CFET devices and the lower-layer conducting line is in a lower conductor layer below all transistors in the CFET devices. The vertical interconnects in the tall cells reduces IR drops and improves the performance of the integrated circuit device, while the speed and current driving capabilities of the transistors in the short cells are not reduced.

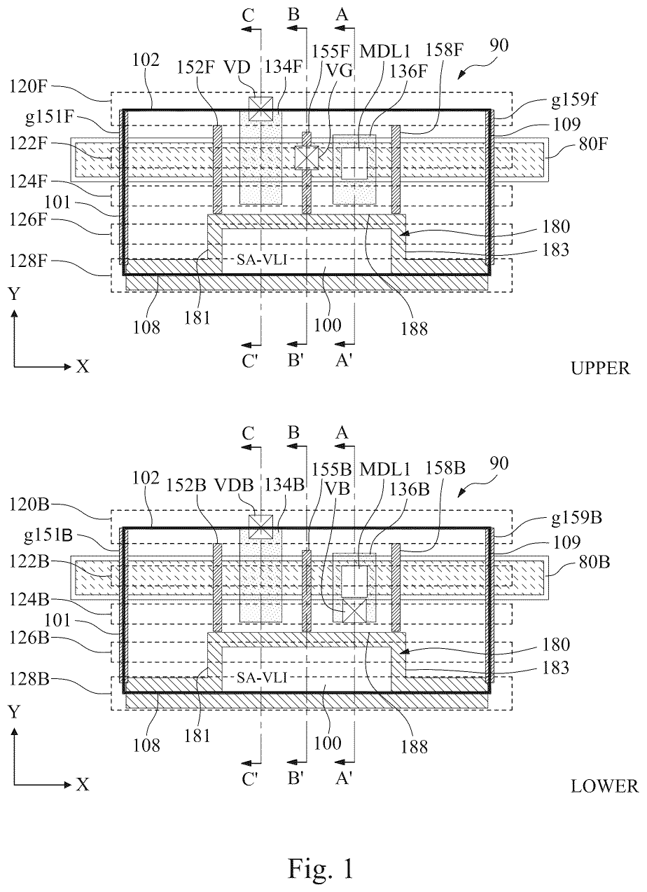

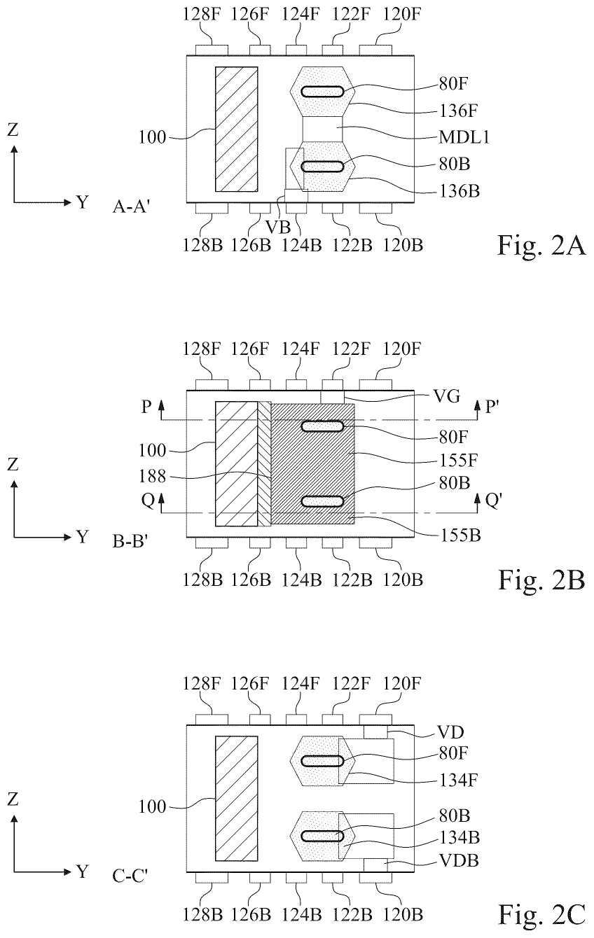

FIG. 1 is a layout diagram of an integrated circuit having a self-aligned vertical interconnect implemented in a circuit cell with an inverter circuit, in accordance with some embodiments. FIGS. 2A-2C are cross-sectional views of an integrated circuit, in accordance with some embodiments. Specifically, the cross-sectional views of the integrated circuit in cutting planes as specified by the lines A-A′, B-B′, and C-C′ in FIG. 1 are correspondingly depicted in FIG. 2A, FIG. 2B, and FIG. 2C.

The layout diagram in FIG. 1 includes an upper portion and a lower portion. The upper portion of the layout diagram includes the layout patterns for specifying the first-type active-region structure 80F, the gate-conductors (such as 152F, 155F, and 158F), the terminal-conductors (such as 134F and 136F), the upper-layer conducting lines (such as 122F, 124F, 126F, and 128F), the upper-layer power rail 120F, the terminal-inter-connector MDLI, the dummy gate-conductors g151F and g159F at the cell boundaries, and various via-connectors. The lower portion of the layout diagram includes the layout patterns for specifying the second-type active-region structure 80B, the gate-conductor (such as 152B, 155B, and 158B), the terminal-conductors (such as 134B and 136B), the lower-layer conducting line (such as 122B, 124B, 126B, and 128B), the lower-layer power rail 120B, the terminal-inter-connector MDLI, the dummy gate-conductors g151B and g159B at the cell boundaries, and various via-connectors.

In the layout diagram of FIG. 1, each of the first-type active-region structure 80F and the second-type active-region structure 80B extends in the X-direction. Various gate-conductors and various terminal-conductors extend in the Y-direction. The first-type active-region structure 80F is stacked with the second-type active-region structure 80B at a front side of a substrate and shifted from the second-type active-region structure along the Z-direction. The stacking of the first-type active-region structure 80F and the second-type active-region structure 80B along the Z-direction is also depicted in the cross-sectional views of FIGS. 2A-2C. In FIG. 1 and FIGS. 2A-2C, the X-direction, the Y-direction, and the Z-direction are mutually orthogonal to each other and form an orthogonal coordinate frame.

In the layout diagram of FIG. 1, the gate-conductor 155F extending in the Y-direction intersects the first-type active-region structure 80F at a channel region of a first-type transistor, and the gate-conductor 155B extending in the Y-direction intersects the second-type active-region structure 80B at a channel region of a second-type transistor. Each of the terminal-conductors 134F and 136F, extending in the Y-direction, intersects the first-type active-region structure 80F at one of the terminal regions of the first-type transistor. Each of the terminal-conductors 134B and 136B, extending in the Y-direction, intersects the second-type active-region structure 80B at one of the terminal regions of the second-type transistor. A terminal region of a transistor is either a source region or a drain region of the transistor.

In some embodiments, the first-type transistor formed in the first-type active-region structure 80F is a PMOS transistor, and the second-type transistor formed in the second-type active-region structure 80B is an NMOS transistor. In some alternative embodiments, the first-type transistor formed in the first-type active-region structure 80F is an NMOS transistor, and the second-type transistor formed in the second-type active-region structure 80B is a PMOS transistor. A CFET device is formed with a first-type transistor stacked with a second-type transistor.

In some embodiments, each of the first-type active-region structure 80F and the second-type active-region structure 80B includes one or more nano-sheets, and consequently, each of the PMOS transistor and the NMOS transistor in FIG. 1 is a nano-sheet transistor. In some embodiments, each of the first-type active-region structure 80F and the second-type active-region structure 80B includes one or more nano-wires, and consequently, each of the PMOS transistor and the NMOS transistor in FIG. 1 is a nano-wire transistor.

In the layout diagram of FIG. 1, the upper-layer power rail 120F extending in the X-direction is in an upper conductor layer, and the lower-layer power rail 120B extending in the X-direction is in a lower conductor layer. As shown in FIGS. 2A-2C, the upper conductor layer is above both the first-type active-region structure 80F and the second-type active-region structure 80B, while the lower conductor layer is below both the first-type active-region structure 80F and the second-type active-region structure 80B. In addition, multiple upper-layer conducting lines (such as 122F, 124F, 126F, and 128F) extending in the X-direction are implemented in the upper conductor layer, and multiple lower-layer conducting lines (such as 122B, 124B, 126B, and 128B) extending in the X-direction are implemented in the lower conductor layer.

Furthermore, as shown in FIG. 1 and FIGS. 2A-2C, the first-type transistor and the second-type transistor are coupled with each other to form an inverter circuit which is configured to receive voltage supplies from the upper-layer power rail 120F and the lower-layer power rail 120B.

In FIG. 1 and FIG. 2A, the terminal-conductor 136F (as the drain terminal of the first-type transistor) and the terminal-conductor 136B (as the drain terminal of the second-type transistor) are conductively connected together through a terminal-inter-connector MDLI. The terminal-conductor 136F and the terminal-conductor 136B form an output node of the inverter circuit. The terminal-conductor 136B is connected to the lower-layer conducting line 124B thorough a via-connector VB, whereby the lower-layer conducting line 124B is configured to receive an output signal of the inverter circuit from the terminal-conductor 136B.

In FIG. 1 and FIG. 2B, the gate-conductor 155F and the gate-conductor 155B are joined together and form an input node of the inverter circuit. The gate-conductor 155F is connected to the upper-layer conducting line 122F through a via-connector VG, whereby the gate-conductor 155F (as of the input node of the inverter circuit) is configured to receive an input signal from the upper-layer conducting line 122F. In some embodiments, the gate-conductor 155B is connected to the lower-layer conducting line 122B through a via-connector VGB (not shown in figure), whereby the gate-conductor 155B (as of the input node of the inverter circuit) is configured to receive an input signal from the lower-layer conducting line 122B.

In FIG. 1 and FIG. 2C, the terminal-conductor 134F, which functions as the source terminal of the first-type transistor, is conductively connected to the upper-layer power rail 120F through a via-connector VD. The terminal-conductor 134B, which functions as the source terminal of the second-type transistor, is conductively connected to the lower-layer power rail 120B through a via-connector VDB. In some embodiments, as the first-type transistor is a PMOS transistor and the second-type transistor is an NMOS transistor, the upper-layer power rail 120F is configured to receive an upper power supply voltage VDD while the lower-layer power rail 120B is configured to receive a lower power supply voltage VSS. In some embodiments, as the first-type transistor is an NMOS transistor and the second-type transistor is a PMOS transistor, the upper-layer power rail 120F is configured to receive a lower power supply voltage VSS while the lower-layer power rail 120B is configured to receive an upper power supply voltage VDD.

In FIG. 1, the first-type transistor formed with the gate-conductor 155F and the second-type transistor formed with the gate-conductor 155B are stacked as a CFET device. The inverter circuit in the circuit cell 90 is implemented with a first CFET device formed with the gate-conductors 155F and 155B. Additional circuits in the circuit cell 90 are implemented with other CFET devices, such as a second CFET device formed with the gate-conductors 152F and 152B and a third CFET device formed with the gate-conductors 158F and 158B. The layout patterns for specifying the terminal-conductors of the second CFET device and the third CFET device and also the layout patterns for specifying additional elements (such as via-connectors and terminal-inter-connectors) in the additional circuits are not explicitly shown in FIG. 1.

The circuit cell 90 is bounded by the dummy gate-conductors g151F and g151B at one side and the dummy gate-conductors g159F and g159B at the other side. The vertical cell boundary 101 of the circuit cell 90 is aligned with the dummy gate-conductors g151F and g151B, and the vertical cell boundary 109 of the circuit cell 90 is aligned with the dummy gate-conductors g159F and g159B. The width of the circuit cell 90 measured along the X-direction is determined by the pitch distance between the dummy gate-conductors g151F and g159F or by the pitch distance between the dummy gate-conductors g151B and g159B.

Each of the dummy gate-conductors 151F and 159F defines a boundary isolation region in the first-type active-region structure 80F at an intersection between the corresponding dummy gate-conductor and the first-type active-region structure 80F. The boundary isolation regions in the first-type active-region structure 80F isolate the active regions (i.e., channel regions, source regions, and drain regions) of the first-type transistors in the circuit cell 90 from the active regions of other first-type transistors (in the first-type active-region structure 80F) in the neighboring circuit cells. Each of the dummy gate-conductors 151B and 159B defines a boundary isolation region in the second-type active-region structure 80B at an intersection between the corresponding dummy gate-conductor and the second-type active-region structure 80B. The boundary isolation regions in the second-type active-region structure 80B isolate the active regions of the second-type transistors in the circuit cell 90 from the active regions of other second-type transistors (in the second-type active-region structure 80B) in the neighboring circuit cells.

The horizontal boundary 102 of the circuit cell 90 extending in the X-direction overlaps with the upper-layer power rail 120F and the lower-layer power rail 120B when viewed in a direction normal to the substrate. In some embodiments, the horizontal boundary 102 extends in the X-direction at the middle line of the upper-layer power rail 120F and/or the lower-layer power rail 120B. The horizontal boundary 108 of the circuit cell 90 extending in the X-direction overlaps with the upper-layer conducting line 128F and the lower-layer conducting line 128B when viewed in a direction normal to the substrate. In some embodiments, each of the upper-layer conducting line 128F and the lower-layer conducting line 128B is a power rail, and the horizontal boundary 108 extends in the X-direction at the middle line of the upper-layer conducting line 128F and/or the lower-layer conducting line 128B. In some embodiments, the height of the circuit cell 90 measured along the Y-direction is determined by the pitch distance between the upper-layer power rail 120F and the upper-layer conducting line 128F or by the pitch distance between the lower-layer power rail 120B and the lower-layer conducting line 128B. In some alternative embodiments, the height of the circuit cell 90 is determined by other elements in the circuit cell.

In FIG. 1, each of the upper portion and the lower portion of the layout diagram also includes the layout patterns for specifying a side-recess 180 and a self-aligned vertical interconnect 100 which is at least partially embedded in the side-recess 180. The side-recess 180 has a boundary surface 188 facing negative Y-direction, a boundary surface 181 facing positive X-direction, a boundary surface 183 facing negative X-direction. Each of the boundary surface 188, the boundary surface 181, and the boundary surface 183 is conformally coated with insulation materials. The conformally coated insulation materials on the boundary surface 188 terminate the gate-conductors 152F, 155F, 158F (as shown in the upper portion of the layout diagram) and the gate-conductors 152B, 155B, 158B (as shown in the lower portion of the layout diagram). The termination of the gate-conductors 155F and 155B by the conformally coated insulation materials on the boundary surface 188 is also shown in the cross-sectional view of FIG. 2B.

The self-aligned vertical interconnect 100, while occupying the space in the side-recess 180, is at least partially embedded in the side-recess 180. The self-aligned vertical interconnect 100 extends in the Z-direction (which is normal to the surface of the substrate) is sufficiently long in length to pass through both the horizontal surface PP′ and the horizontal surface QQ′ as shown in FIG. 2B. Here, the horizontal surface PP′ is at an upper edge of the first-type active-region structure 80F and the horizontal surface QQ′ is at a lower edge of the second-type active-region structure 80B, while each of the horizontal surface PP′ and the horizontal surface QQ′ is parallel to the surface of the substrate.

In some embodiments, the self-aligned vertical interconnect 100 conductively connects the upper-layer conducting line 126F with lower-layer conducting line 126B (where the connection is not explicitly shown in the figure). In some embodiments, the self-aligned vertical interconnect 100 is sufficiently long to directly connect the upper-layer conducting line 126F with the lower-layer conducting line 126B. In some embodiments, the self-aligned vertical interconnect 100 connects the upper-layer conducting line 126F with the lower-layer conducting line 126B though one or more via-connectors. In some embodiments, one or both of the upper-layer conducting line 126F and the lower-layer conducting line 126B is configured to receive a supply voltage. Similarly, in some embodiments, the self-aligned vertical interconnect 100 conductively connects the upper-layer conducting line 128F with the lower-layer conducting line 128B (where the connection is not explicitly shown in the figure), while each of the upper-layer conducting line 128F and the lower-layer conducting line 128B is implemented as a power rail.

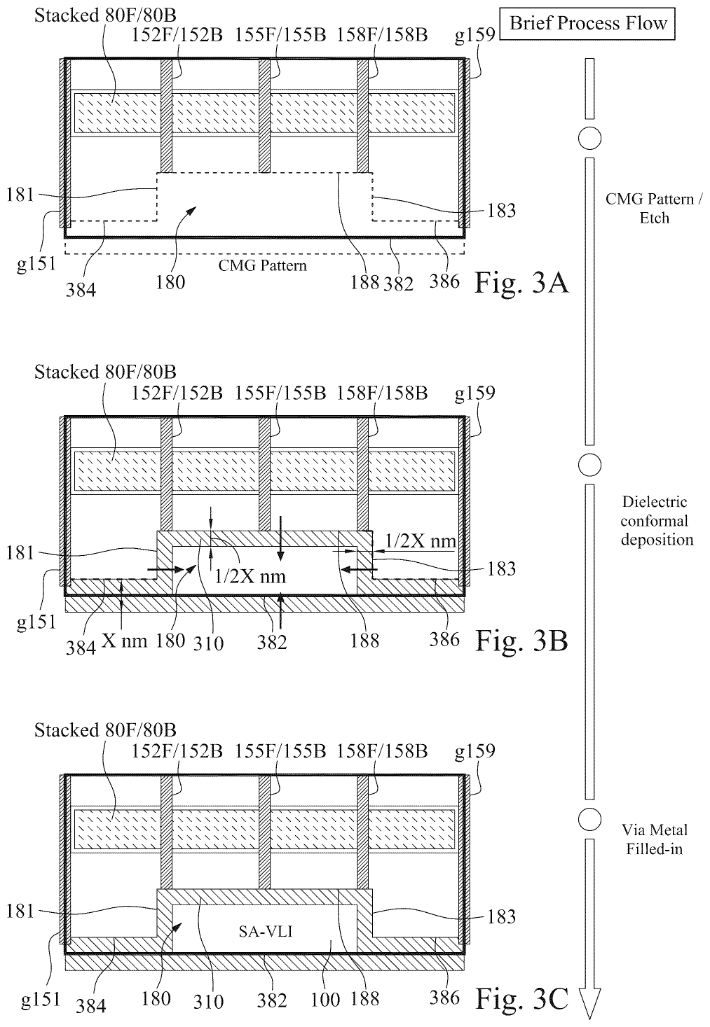

FIGS. 3A-3C are schematics of a process flow for fabricating a self-aligned vertical interconnect embedded partially in a side-recess adjacent to active-region structures, in accordance with some embodiments. The side-recess 180 in FIGS. 3A-3C is fabricated after the fabrication of some of the elements in the integrated circuit. As shown in FIG. 3A, before the side-recess 180 is fabricated, the first-type active-region structure 80F and the second-type active-region structure 80B stacked with each other are fabricated. The gate-conductors 152F, 155F, and 158F and the gate-conductors 152B, 155B, and 158B are also fabricated before the side-recess is fabricated. In addition, various terminal-conductors (not shown explicitly in FIG. 3A) are also fabricated as well before the side-recess 180 is fabricated.

As shown in FIG. 3A, in the process of fabricating the side-recess 180, an exposed area defined by a mask (which is determined a CMG pattern) is subject to a dry etching process. In some embodiments, in the layout design process, the CMG pattern is a layout pattern for specifying the cutting of metal gates. After the dry etching process, an emptied space including the side-recess 180 is created in the exposed area defined by the mask. The boundary surface 188 of the side-recess 180 terminates each of the gate-conductors 152F, 155F, and 158F and each of the gate-conductors 152B, 155B, and 158B. That is, the parts of the gate-conductors 152F/152B, 155F/155B, and 158F/158B which extend across into the exposed area defined by the mask (shown as the CMG pattern) are removed during the dry etching process. The depth of the side-recess 180 along the Y-direction is related to the amount or the length of materials removed from the gate-conductors, which is terminated by the mask (shown as the CMG pattern). The length of the side-recess 180 along the X-direction is determined by the distance between the boundary surface 181 and the boundary surface 183, which is also terminated by the mask (shown as the CMG pattern).

In the process of fabricating the side-recess 180, as shown in FIG. 3A, some materials of the dummy gate-conductors g151 and g159 at the vertical cell boundaries of the circuit cell are also removed, and consequently the dummy gate-conductors g151 and g159 are terminated correspondingly at some boundary surfaces 384 and 386 of the emptied space created in the exposed area defined by the mask. In some alternative embodiments, each of the dummy gate-conductors g151 and g159 is not terminated by the boundary surface 384 or 386 of the emptied space created in the exposed area defined by the mask.

After the side-recess 180 is fabricated, in the next step, as shown in FIG. 3B, dielectric materials 310 are coated conformally onto the boundary surfaces (i.e., 188, 181, and 183) of the side-recess 180 and various other boundary surfaces (e.g., 382, 384, and 386) of the emptied space created in the earlier step with the dry etching process.

After the step of conformal deposition, in the next step, as shown in FIG. 3C, the remaining empty space bounded with the dielectric materials on the boundary surfaces (i.e., 188, 181, 183, and 386) is filed with metallic materials, whereby the self-aligned vertical interconnect 100 is formed in the circuit cell.

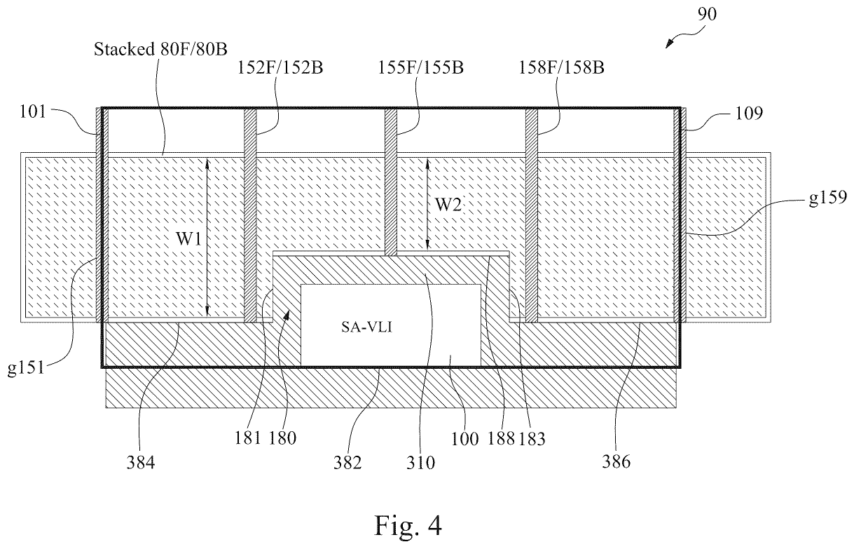

In the embodiments as shown in FIG. 1, the first-type active-region structure 80F has a uniform width between the dummy gate-conductors g151F and g159F, and the second-type active-region structure 80B has a uniform width between the dummy gate-conductors g151B and g159B. That is, the stacked active-region structure 80F/80B has a uniform width between the vertical cell boundary 101 and the vertical cell boundary 109 of the circuit cell. In some embodiments as shown in FIG. 4, the stacked active-region structure 80F/80B does not have a uniform width between the vertical cell boundary 101 and the vertical cell boundary 109 of the circuit cell.

FIG. 4 is a schematic of a simplified layout diagram of a circuit cell, in accordance with some embodiments. In FIG. 4, the circuit cell is bounded in the X-direction by the dummy gate-conductor g151 at the vertical cell boundary 101 and the dummy gate-conductor g159 at the vertical cell boundary 109. The gate-conductors 152F/152B, 155F/155B, and 158F/158B correspondingly intersect the first-type wide active-region structure and the second-type wide active-region structure of the stacked active-region structure 80F/80B. While each of the gate-conductors 152F/152B, 155F/155B, and 158F/158B in FIG. 1 is terminated by the boundary surface 188 of the side-recess 180, only the gate-conductors 155F/155B in FIG. 4 are terminated by the boundary surface 188 of the side-recess 180, but the gate-conductors 152F/152B and 158F/158B are correspondingly terminated by the conformally coated insulation materials on the boundary surfaces 384 and 386 (which are not in the rectangular side-recess accommodating the self-aligned vertical interconnect 100). Consequently, the transistors in the CFET device formed with the gate-conductors 155F/155B have a gate width which is equal to the reduced width W2 of the stacked active-region structure 80F/80B, the transistors in the CFET device formed with the gate-conductors 152F/152B or the gate-conductors 155B/158B have a gate width which is equal to the wide width W1 of the stacked active-region structure 80F/80B. Here, the gate wide width W1 is larger than the gate reduced width W2. Even though the gate-conductors 155F/155B are shortened to provide the space to accommodate the self-aligned vertical interconnect 100, the gate-conductors in other areas of the circuit cell are nevertheless maintained at a longer length. Consequently, the transistors formed with gate-conductors in the other areas of the circuit cell maintain a larger driving strength and a larger current carry capability than the transistors formed with the gate-conductors 155F/155B.

In some embodiments, an integrated circuit includes multiple tall cells arranged in a first row and multiple short cells arranged in a second row. Self-aligned vertical interconnects are implemented in one or more of the tall cells in the first row, but there is no self-aligned vertical interconnect in the short cells in the second row, at least within a portion of the integrated circuit. The CFET devices in the tall cells are implemented with wide active-region structures. The CFET devices in the short cells are implemented with narrow active-region structures. The height of a tall cell in the first row is larger than the height of a short cell in the second row.

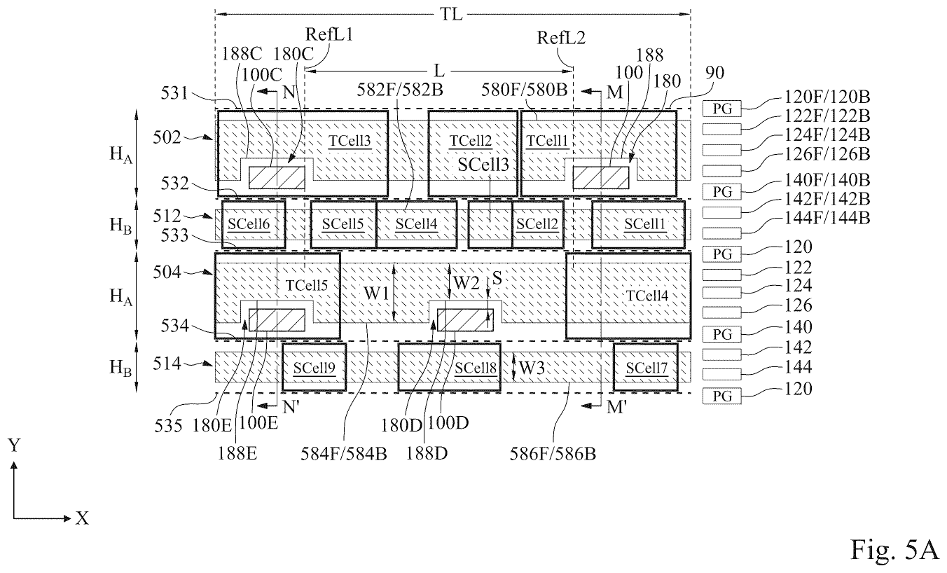

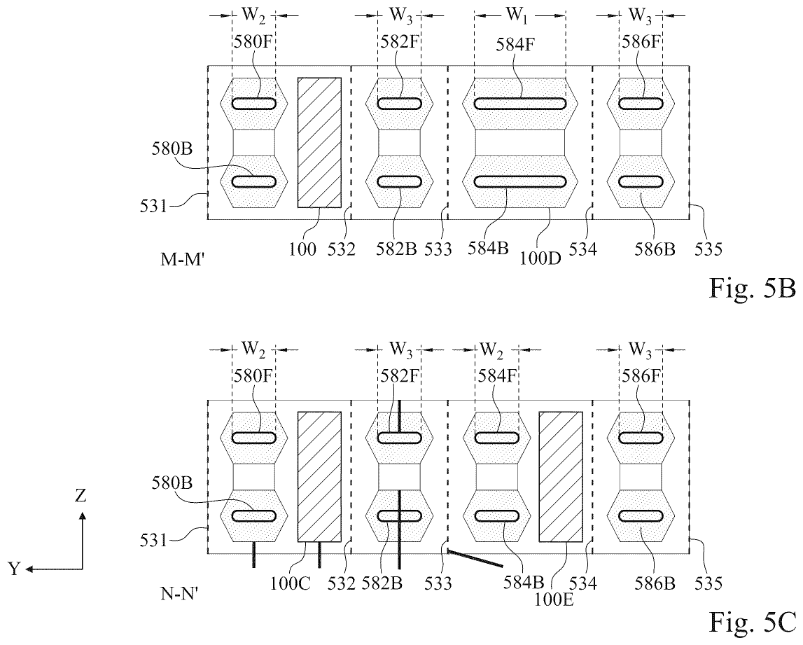

FIG. 5A is a schematic of a simplified layout diagram of a portion of an integrated circuit, in accordance with some embodiments. In FIG. 5A, the portion of the integrated circuit includes tall cells arranged in cell rows 502 and 504 and also short cells arranged in cell rows 512 and 514. Several tall cells are depicted in the cell rows 502 and 504 as examples, and several short cells are depicted in the cell rows 512 and 514 also as examples. Additional tall cells and short cells, while possibly exist, are not explicitly shown in the cell rows 502 and 504 or in the cell rows 512 and 514.

Each of the cell rows 502 and 504 for the tall cells has a height which is larger than a height of the cell row 512 or 514 for the short cells. The height of a tall cell is larger than the height of a short cell. In FIG. 5A, tall cells TCell1, TCell2, and TCell3 are arranged in the cell row 502 (which is between the row boundaries 531 and 532). The CFET devices in the tall cells TCell1, TCell2, and TCell3 are implemented with the stacked wide active-region structures 580F/580B. Short cells SCell1, SCell2, SCell3, SCell4, SCell5, and SCell6 are arranged in the cell row 512 (which is between the row boundaries 532 and 533). The CFET devices in the short cells SCell1-SCell6 are implemented with the stacked narrow active-region structures 582F/582B. Tall cells TCell4 and TCell5 are arranged in the cell row 504 (which is between the row boundaries 533 and 534). The CFET devices in the tall cells TCell4 and TCell5 are implemented with the stacked wide active-region structures 584F/584B. Short cells SCell7, SCell8, and SCell9 are arranged in the cell row 514 (which is between the row boundaries 534 and 535). The CFET devices in the short cells SCell7-SCell9 are implemented with the stacked narrow active-region structures 586F/586B.

Each of the tall cells TCell1, TCell3, and TCell5 has correspondingly a self-aligned vertical interconnect 100, 100C, or 100E. Each of the tall cells TCell1, TCell3, and TCell5 also has a corresponding side-recess (i.e., 180, 180C or 180E) implemented to accommodate a self-aligned vertical interconnect. The self-aligned vertical interconnects 100 and 100C extending in the Z-direction (which is perpendicular to both the X-direction and the Y-direction) is partially embedded in a corresponding side-recess (i.e., 180 or 180C) adjacent to the stacked active-region structure 580F/580B. The self-aligned vertical interconnect 100E extending in the Z-direction is partially embedded in a corresponding side-recess 180E adjacent to the stacked active-region structure 584F/584B. Another self-aligned vertical interconnect 100D, which is not in a tall cell, is partially embedded in a corresponding side-recess (i.e., 180D) adjacent to the stacked active-region structure 584F/584B.

Each of the side-recesses 180, 180C, 180D, and 180E has a corresponding boundary surface (i.e., 188, 188C, 188D, or 188E) which is conformally coated with insulation materials (not shown in FIG. 5A). Each of the self-aligned vertical interconnects 100, 100C, 100D, and 100E is separated from the corresponding stacked active-region structure (580F/580B or 584F/584B) by the insulation materials on the corresponding boundary surface (i.e., 188, 188C, 188D, or 188E).

FIGS. 5B-5C are cross-sectional views of an integrated circuit in FIG. 5A, in accordance with some embodiments. Specifically, the cross-sectional views of the integrated circuit in cutting planes as specified by the lines M-M′ and N-N′ in FIG. 5A are correspondingly depicted in FIG. 5B and FIG. 5C.

As shown in FIGS. 5A-5C, in the cell row 502 between the row boundaries 531 and 532, the stacked wide active-region structures 580F/580B includes a first-type wide active-region structure 580F and a second-type wide active-region structure 580B which are stacked with each other. In the cell row 512 between the row boundaries 532 and 533, the stacked narrow active-region structures 582F/582B includes a first-type narrow active-region structure 582F and a second-type narrow active-region structure 582B which are stacked with each other. In the cell row 504 between the row boundaries 533 and 534, the stacked wide active-region structures 584F/584B includes a first-type wide active-region structure 584F and a second-type wide active-region structure 584B which are stacked with each other. In the cell row 514 between the row boundaries 534 and 535, the stacked narrow active-region structures 586F/586B includes a first-type narrow active-region structure 586F and a second-type narrow active-region structure 586B which are stacked with each other.

In FIG. 5A, the width of the stacked wide active-region structures (e.g., 580F/580B or 584F/584B), in regions without narrowing by a side-recess, is the wide width W1, but the width of the stacked wide active-region structures (e.g., 580F/580B or 584F/584B), in regions narrowed by a side-recess is the reduced width W2. The width of the stacked narrow active-region structures (e.g., 582F/582B or 586F/586B) is the narrow width W3.

In an example as shown in FIG. 5B, in the cutting plane M-M′, the width of at least one of the first-type wide active-region structure 580F and the second-type wide active-region structure 580B is the reduced width W2, and the width of at least one of the first-type wide active-region structure 584F and the second-type wide active-region structure 584B is the wide width W1 (which is larger than the reduced width W2). In an example as shown in FIG. 5C, in the cutting plane N-N′, the width of at least one of the first-type wide active-region structure 580F and the second-type wide active-region structure 580B is the reduced width W2, and similarly the width of at least one of the first-type wide active-region structure 584F and the second-type wide active-region structure 584B is also the reduced width W2.

In an example as shown in FIGS. 5B-5C, in each of the cutting plane M-M′ and the cutting plane N-N′, the width of at least one of the first-type narrow active-region structure 582F and the second-type narrow active-region structure 582B is the narrow width W3 (which is smaller than the wide width W1), and similarly the width of at least one of the first-type narrow active-region structure 586F and the second-type narrow active-region structure 586B is also the narrow width W3 (which is smaller than the wide width W1).

In FIGS. 5B-5C, in some embodiments, each of the first-type active-region structures (i.e., 580F, 582F, 584F, and 586F) and the second-type active-region structures (i.e., 580B, 582B, 584B, and 586B) includes multiple nanostructures (such as nano-sheets or nano-wires). In some example implementations, the multiple nanostructures in a first-type active-region structure or in a second-type active-region structure includes multiple stacked nano-sheets (such as two, three, or four stacked nano-sheets). In some embodiments, a metal gate surrounding the multiple nanostructures in the first-type active-region structure forms the gate terminal of a first-type transistor, and a conductive segment on either side of the metal gate which is in conductive contacts with the multiple nanostructures forms the source terminal or the drain terminal of the first-type transistor. Similarly, a metal gate surrounding the multiple nanostructures in the second-type active-region structure forms the gate terminal of a second-type transistor, and a conductive segment on either side of the metal gate which is in conductive contacts with the multiple nanostructures forms the source terminal or the drain terminal of the second-type transistor. In some embodiments, the first-type transistor is a PMOS transistor, and the second-type transistor is an NMOS transistor. In some embodiments, the first-type transistor is an NMOS transistor, and the second-type transistor is a PMOS transistor.

In FIG. 5A, the height of each cell row (i.e., 502 and 504) containing the tall cells is the height H_{A}, and the height of each tall cell is equal to or smaller than the height H_{A}. In some implementations, the height of each tall cell is equal to the height H_{A}. The height of each tall cell row is measured along the Y-direction. In FIG. 5A, the height of each cell row (i.e., 512 or 514) containing the short cells is the height H_{B}, and the height of each short cell is equal to or smaller than the height H_{B}. In some implementations, the height of each short cell is equal to the height H_{B}. The height of each short cell row is measured along the Y-direction.

In some embodiments, the width of the stacked wide active-region structures, the width of the stacked narrow active-region structures, and the depth of each side-recess all scale with the height H_{A} of the cell row containing the tall cells. In some example implementations, the wide width W1 of the stacked wide active-region structures without narrowing by a side-recess is in a range from 0.5 H_{A} to 0.7 H_{A}, the reduced width W2 of the stacked wide active-region structures narrowed by a side-recess is in a range from 0.3 H_{A} to 0.4 H_{A}, the narrow width W3 of the stacked narrow active-region structures is in a range from 0.3 H_{A} to 0.4 H_{A}. Additionally, in FIG. 5A, the separation (measured along the Y-direction) between a self-aligned vertical interconnect (e.g., 100D) and the adjacent stacked wide active-region structures (e.g., 584F/584B) is the distance S. In some example implementations, the distance S is in a range from 0.1 H_{A} to 0.2 H_{A}. In some embodiments, the depth B of the side-recess is between 0.2 H_{A} to 0.3 H_{A}.

In FIG. 5A, while some of the tall cells are implemented with self-aligned vertical interconnects, none of the short cells is implemented with a self-aligned vertical interconnect. In the portion of the integrated circuit in FIG. 5A, there is no side-recess in the cell rows 512 and 514 containing short cells, and each of the stacked narrow active-region structures 582F/582B and 586F/586B has a uniform width, at least in the portion of the integrated circuit as shown in the figure. Each of the first-type narrow active-region structure and the second-type narrow active-region structure (in the cell row 512 or 514) extends in the X-direction with a uniform width for a range longer than the distance L, which is the distance separating the self-aligned vertical interconnects 100 and 100C. In fact, the width of the stacked narrow active-region structures (e.g., 582F/582B or 586F/586B) is uniform for a range which is at least as long as the total length TL of the portion of the integrated circuit as shown in the figure.

In FIG. 5A, the segment of the stacked wide active-region structures 580F/580B adjacent to the side-recess 180 and the side-recess 180C has a reduced width such as W2, while the segment of the stacked wide active-region structures 580F/580B between the side-recess 180 and the side-recess 180C has a wide width such as W1.

In the example embodiments as shown in FIG. 5A, none of the short cells as shown have a self-aligned vertical interconnect inside. In some embodiments, at least three short cells consecutively arranged in a row of short cells are absence of any self-aligned vertical interconnect. For example, the short cells SCell2, SCell3, and SCell4 (which are consecutively arranged in the cell row 512) are all absence of any self-aligned vertical interconnect. The short cells SCell3, SCell4, and SCell5 (which are also consecutively arranged in the cell row 512) are also absence of any self-aligned vertical interconnect. In some embodiments, at least four short cells consecutively arranged in a row of short cells are absence of any self-aligned vertical interconnect. For example, the short cells SCell2, SCell3, SCell4, and SCell5 are all absence of any self-aligned vertical interconnect. The short cells SCell2, SCell3, SCell4, and SCell5 are consecutively arranged in the cell row 512 within the distance L, which measures the distance separating the self-aligned vertical interconnects 100 and 100C.

In FIG. 5A, the integrated circuit also includes power grids at each of the row boundaries 531-535 and includes horizontal conducting tracks between the power grids. While each of the power grids and horizontal conducting tracks extends in the X-direction, the Y-coordinates of the power grids and the horizontal conducting tracks are depicted schematically on the right side of the FIG. 5A. The width of each of the power grids and the horizontal conducting tracks is also depicted schematically on the right side of the FIG. 5A.

In FIG. 5A, a power grid track 120 (which represents an upper-layer power rail 120F and a lower-layer power rail 120B) is implemented at each of the row boundaries 531, 533, and 535. An example of the upper-layer power rail 120F and the lower-layer power rail 120B in the power grid track 120 is shown in FIGS. 2A-2C. A power grid track 140 (which represents an upper-layer power rail and the lower-layer power rail) is implemented at each of the row boundaries 532 and 534. In one embodiment, a power grid track 140 is implemented with an upper-layer conducting line 128F and a lower-layer conducting line 128B at the horizontal boundary 108 of the circuit cell 90, as shown in the example of FIGS. 2A-2C.

In FIG. 5A, a group of three horizontal conducting tracks 122, 124, and 126 is implemented within each of the cell rows 502 and 504. Here, the horizontal conducting tracks 122, 124, and 126 correspondingly represent the upper-layer conducting lines 122F, 124F, and 126F and the lower-layer conducting lines 122B, 124B, and 126B, such as in the example as shown in FIGS. 2A-2C. A group of two horizontal conducting tracks 142 and 144 (each of which represents an upper-layer conducting line and a lower-layer conducting line) is implemented within each of the cell rows 512 and 514.

In the example as shown in FIGS. 5A-5C, the width of the stacked wide active-region structures is narrowed in some regions by a side-recess. In some alternative embodiments, the width of the stacked wide active-region structures remains uniform in the cell rows 502 and 504.

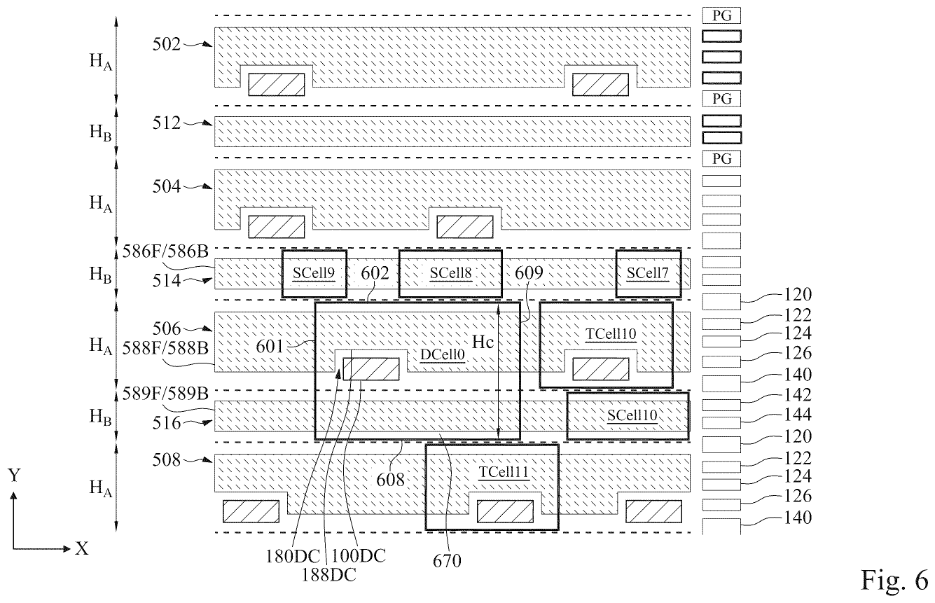

In some embodiments, such as in FIG. 6, an integrated circuit includes one or more double-height circuit cells which are implemented with the self-aligned vertical interconnects. FIG. 6 is a schematic of a simplified layout diagram of a portion of an integrated circuit, in accordance with some embodiments. In FIG. 6, a few selected tall cells and a few selected short cells are depicted in the figure. The tall cells depicted in FIG. 6 include the tall cell TCell10 in the cell row 506 and the tall cell TCell11 in the cell row 508. The short cells depicted in FIG. 6 include the short cells SCell7, SCell8, and SCell9 in the cell row 514 and the short cell SCell10 in the cell row 516.

FIG. 6 is a schematic of a simplified layout diagram of a portion of an integrated circuit, in accordance with some embodiments. In FIG. 6, a double height cell DCell0 is also depicted in the figure. The double height cell DCell0 occupies both the cell row 506 and the cell row 516. The double height cell DCell0 is bounded along the X-direction by the vertical cell boundaries 601 and 609. The double height cell DCell0 is bounded along the Y-direction by the horizontal cell boundaries 602 and 608. Each of the horizontal cell boundaries 602 and 608 of the double height cell DCell0 overlaps with a power grid track 120 when viewed in a direction normal to the substrate. Each power grid track 120 includes an upper-layer power rail 120F and a lower-layer power rail 120B which are stacked with each other. The upper-layer power rails at the horizontal cell boundaries 602 and 608 are configured to receive a same first supply voltage (such as the upper supply voltage VDD). The lower-layer power rail at the horizontal cell boundaries 602 and 608 are configured to receive a same second supply voltage (such as the lower supply voltage VSS).

In FIG. 6, other power grid tracks “PG” extending in the X-direction are schematically presented in the figure. The horizontal conducting tracks “cLn” extending in the X-direction are also schematically presented in the figure. Each power grid track “PG” corresponds to an upper-layer power rail and a lower-layer power rail. Each horizontal conducting track “cLn” corresponds to an upper-layer conducting line and a lower-layer conducting line.

As double height cell DCell0 occupies both the cell row 506 containing the tall cells and the cell row 516 containing the short cells, the double height cell DCell0 has a height H_{C}=H_{A}+H_{B}. That is, the height H_{C} of the double height cell DCell0 is the sum of the height H_{A} of the cell row containing the tall cells and the height H_{B} of the cell row containing the short cells.

The double height cell DCell0 includes wide CFET devices implemented in the stacked wide active-region structures 588F/588B and narrow CFET devices implemented in the stacked narrow active-region structures 589F/589B. Each wide CFET device in the double height cell DCell0 includes a first-type wide transistor in a first-type wide active-region structure 588F and a second-type wide transistor in a second-type wide active-region structure 588B. Each narrow CFET device in the double height cell DCell0 includes a first-type narrow transistor in a first-type narrow active-region structure 589F and a second-type narrow transistor in a second-type narrow active-region structure 589B.

Each of the first-type wide active-region structure 588F and the second-type wide active-region structure 588B has a boundary isolation region at the vertical cell boundaries 601 and 609. The boundary isolation regions in the stacked wide active-region structures 588F/588B isolate the active regions of the wide CFET devices in the double height cell DCell0 from the active regions of other wide transistors in the neighboring circuit cells. Each of the first-type narrow active-region structure 589F and the second-type narrow active-region structure 589B also has a boundary isolation region at the vertical cell boundaries 601 and 609. The boundary isolation regions in the stacked narrow active-region structures 589F/589B isolate the active regions of the narrow CFET devices in the double height cell DCell0 from the active regions of other narrow transistors in the neighboring circuit cells.

The double height cell DCell0 also includes a self-aligned vertical interconnect 100DC partially embedded in a side-recess 180DC adjacent to the stacked wide active-region structures 588F/588B. The boundary surface 188DC of the side-recess 180DC is conformally coated with insulation materials. The conformally coated insulation materials on the boundary surface 188DC terminate one or more gate-conductors intersecting the first-type wide active-region structure 588F and/or the second-type wide active-region structure 588B in the double height cell DCell0. The stacked narrow active-region structures 589F/589B have a uniform width between the vertical cell boundaries 601 and 609. None of the self-aligned vertical interconnects of the double height cell DCell0 is implemented in the region 670 between the stacked narrow active-region structures 589F/589B and the horizontal cell boundary 608. In some embodiments, none of the self-aligned vertical interconnects of the double height cell DCell0 is implemented in a region separating the power rails 120F/120B from the first-type narrow active-region structure 589F and the second-type narrow active-region structure 589B.

In the double height cell DCell0 of FIG. 6, the self-aligned vertical interconnect 100DC partially embedded in the side-recess 180DC adjacent to the stacked wide active-region structures 588F/588B is provided as an example. In some embodiments, a double height cell includes two or more self-aligned vertical interconnects, and each self-aligned vertical interconnect in the double height cell is accommodated by a side-recess adjacent to the stacked wide active-region structures 588F/588B.

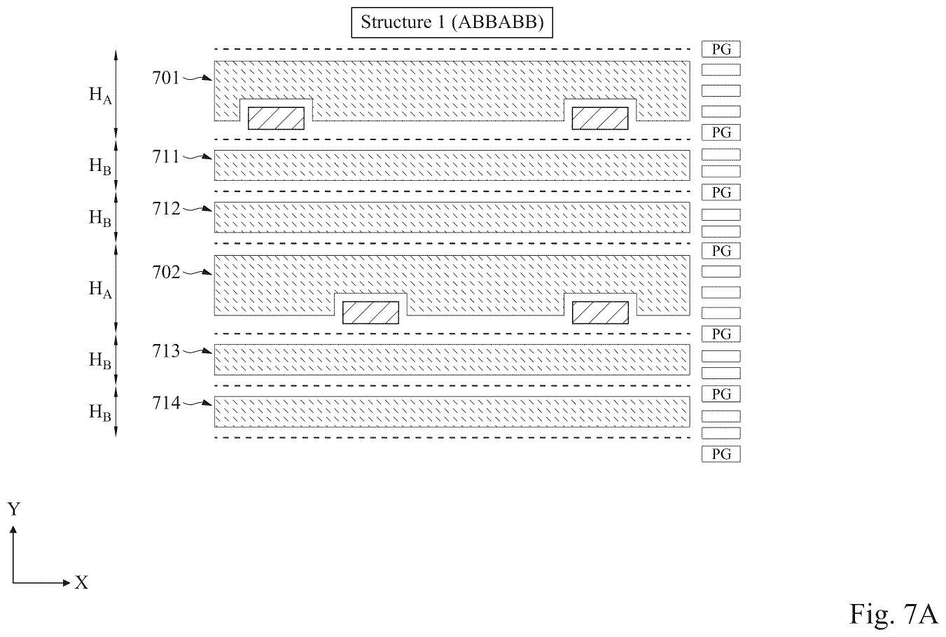

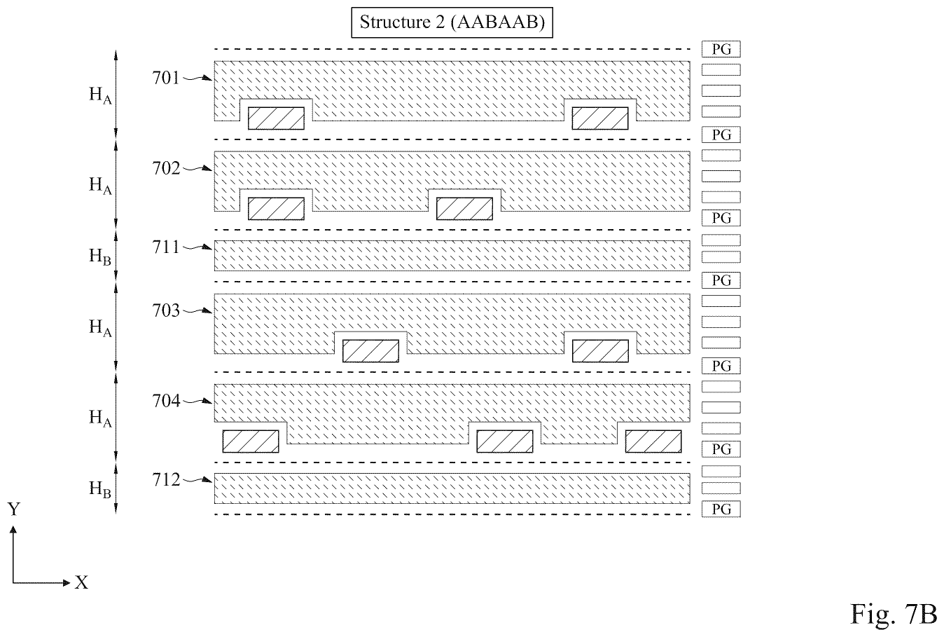

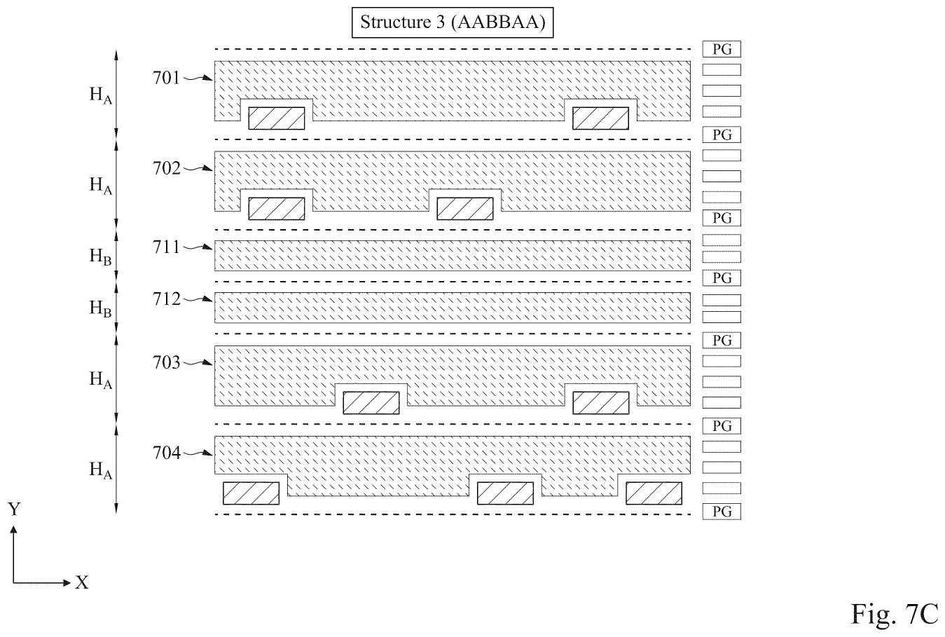

In the example layout design of FIG. 5A and FIG. 6, one row of short cells is between two rows of tall cells, and one row of tall cells is between two rows of short cells. The layout arrangement in FIG. 5A and FIG. 6 can be characterized as an “ABABAB” design. Alternative layout arrangements between rows of tall cells and rows of short cells are depicted in FIGS. 7A-7C. FIGS. 7A-7C are schematics of simplified layout diagrams of a portion of an integrated circuit, in accordance with some embodiments.

In FIG. 7A, the portion of the integrated circuit includes cell rows 701 and 702 having tall cells and cell rows 711-714 having short cells. With the “ABBABB” layout arrangement of FIG. 7A, a pair of two adjacent rows of short cells are inserted between two rows of tall cells. For example, a pair of the cell rows 711 and 712 having short cells is inserted between the cell rows 701 and 702 having tall cells.

In FIG. 7B, the portion of the integrated circuit includes cell rows 701-704 having tall cells and cell rows 711 and 712 having short cells. With the “AABAAB” layout arrangement of FIG. 7B, a pair of two adjacent rows of tall cells are inserted between two rows of short cells. For example, a pair of the adjacent cell rows 703 and 704 having tall cells are inserted between the cell rows 711 and 712 having short cells.

In FIG. 7C, the portion of the integrated circuit includes cell rows 701-704 having tall cells and cell rows 711 and 712 having short cells. With the “AABBAA” layout arrangement of FIG. 7C, a pair of two adjacent rows of short cells are inserted between a first pair of two adjacent rows of tall cells and a second pair of two adjacent rows of tall cells. In addition, a pair of two adjacent rows of tall cells are inserted between a first pair of two adjacent rows of short cells and a second pair of two adjacent rows of short cells (not explicitly shown in the figure). For example, a pair of the adjacent cell rows (i.e., 711 and 712) having short cells are inserted between a first pair of the adjacent cell rows (i.e., 701 and 702) having tall cells and a second pair of the adjacent cell rows (i.e., 703 and 704) having tall cells. A pair of the adjacent cell rows (i.e., 703 and 704) having tall cells are inserted between a first pair of the adjacent cell rows (i.e., 711 and 712) having short cells and a second pair of adjacent cell rows having short cells (which are not explicitly shown in the figure).

In FIGS. 7A-7C, power grid tracks “PG” extending in the X-direction and horizontal conducting tracks “cLn” extending in the X-direction are schematically presented in the figure. Each power grid track “PG” corresponds to an upper-layer power rail and a lower-layer power rail. Each horizontal conducting track “cLn” corresponds to an upper-layer conducting line and a lower-layer conducting line.

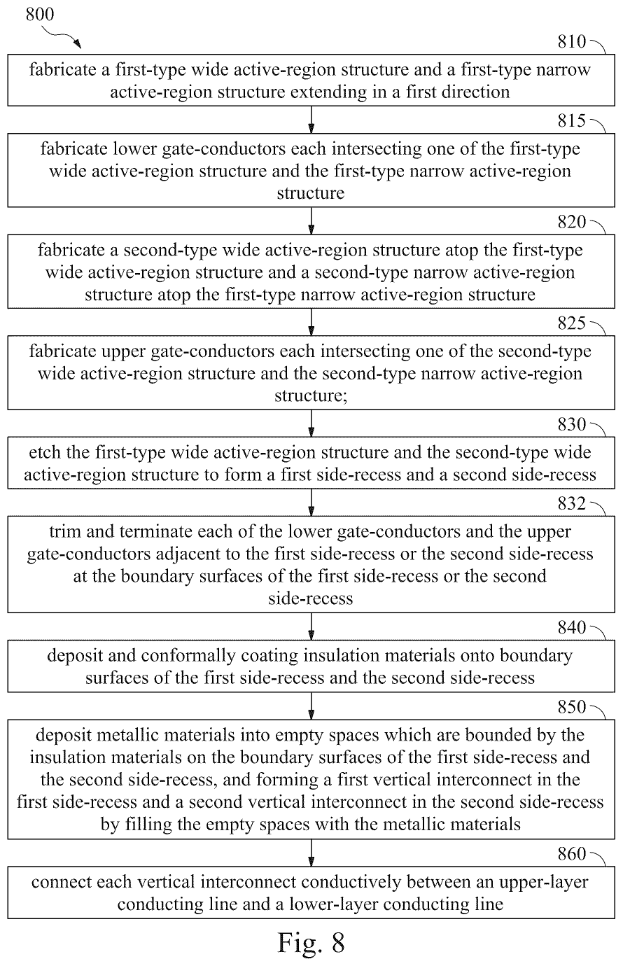

FIG. 8 is a flowchart of a method 800 of manufacturing an integrated circuit (IC) having CFET devices, in accordance with some embodiments. It is understood that additional operations may be performed before, during, and/or after the method 800 depicted in FIG. 8, and that some other processes may only be briefly described herein.

In operation 810, a first-type wide active-region structure and a first-type narrow active-region structure extending in a first direction are fabricated. In the example as shown in FIGS. 5A-5C, the wide active-region structure (i.e., 580B) and the narrow active-region structure (i.e., 582B) at the bottom of stacked active-region structures are fabricated.

In operation 815, lower gate-conductors each intersecting one of the first-type wide active-region structure and the first-type narrow active-region structure are fabricated. In the example as shown in FIGS. 5A-5C and the lower portion of FIG. 1, the gate-conductors 152B, 155B, and 158B are fabricated.

In operation 820, a second-type wide active-region structure is fabricated atop the first-type wide active-region structure and a second-type narrow active-region structure is fabricated atop the first-type narrow active-region structure. In the example as shown in FIGS. 5A-5C, the wide active-region structure (i.e., 580F) and the narrow active-region structure (i.e., 582F) at the top of stacked active-region structures are fabricated.

In operation 825, upper gate-conductors each intersecting one of the second-type wide active-region structure and the second-type narrow active-region structure is fabricated. In the example as shown in FIGS. 5A-5C and the upper portion of FIG. 1, the gate-conductors 152F, 155F, and 158F are fabricated.

In operation 830, each of the first-type wide active-region structure and the second-type wide active-region structure is etched to form a first side-recess and a second side-recess. None of the first-type narrow active-region structure and the second-type narrow active-region structure is etched in operation 830. In the example as shown in FIGS. 5A-5C and FIG. 3A, the first-type wide active-region structure and the second-type wide active-region structure in the wide active-region structure 580F/580B are etched to form the side-recess 180 and the side-recess 180C. The first-type narrow active-region structure and the second-type narrow active-region structure in the narrow active-region structure 582F/582B are not etched for forming any side-recess.

In operation 832, each of the lower gate-conductors and the upper gate-conductors adjacent to the first side-recess or the second side-recess is trimmed and terminated at the boundary surfaces of the first side-recess or the second side-recess. In the example as shown in FIG. 3A, the gate-conductors 152F/152B, 155F/155B, and 158F/158B are trimmed and terminated at the boundary surface 188.

In operation 840, insulation materials are deposited onto boundary surfaces of the first side-recess and the second side-recess, whereby boundary surfaces are conformally coated with the insulation materials. In the example as shown in FIG. 3B, dielectric materials 310 are coated conformally onto the boundary surfaces (i.e., 188, 181, and 183) of the side-recess 180. In the example as shown in FIGS. 5A-5C, insulation materials are coated conformally onto the boundary surfaces of the side-recess 180 and the side-recess 180C.

In operation 850, metallic materials are deposited into the empty spaces bounded with the insulation materials on the boundary surfaces of the first side-recess and the second side-recess, and a first vertical interconnect in the first side-recess and a second vertical interconnect in the second side-recess are formed by filling the empty spaces with the metallic materials. In the example as shown in FIG. 3C, the empty spaces bounded with the dielectric materials on the boundary surfaces of the side-recess 180 are filled with metallic materials, and the self-aligned vertical interconnect 100 is formed. In the example as shown in FIGS. 5A-5C, the empty space bounded with the insulation materials on the boundary surfaces of the side-recess 180 and the side-recess 180C are filed with metallic materials, whereby the self-aligned vertical interconnect 100 and the self-aligned vertical interconnect 100C are formed.

In operation 860, upper-layer conducting lines and lower-layer conducting lines are formed and whereby each vertical interconnect is connected conductively between an upper-layer conducting line and a lower-layer conducting line. In the example as shown in FIGS. 5A-5C and FIGS. 2A-2C, the upper-layer conducting line 126F is conductively connected to the lower-layer conducting line 126B though some implementations of the self-aligned vertical interconnect 100.

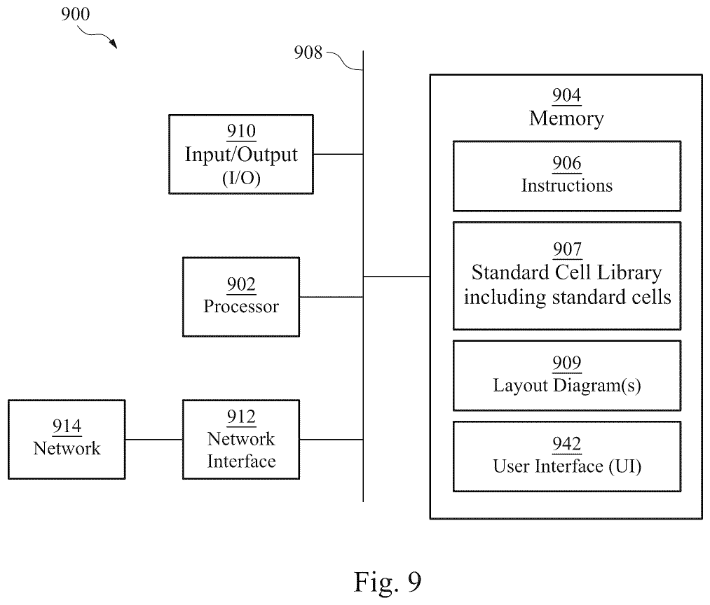

FIG. 9 is a block diagram of an electronic design automation (EDA) system 900 in accordance with some embodiments.

In some embodiments, EDA system 900 includes an automatic placement and routing (APR) system. Methods described herein of designing layout diagrams represent wire routing arrangements, in accordance with one or more embodiments, are implementable, for example, using EDA system 900, in accordance with some embodiments.

In some embodiments, EDA system 900 is a general purpose computing device including a hardware processor 902 and a non-transitory, computer-readable storage medium 904. Storage medium 904, amongst other things, is encoded with, i.e., stores, computer program code 906, i.e., a set of executable instructions. Execution of instructions 906 by hardware processor 902 represents (at least in part) an EDA tool which implements a portion or all of the methods described herein in accordance with one or more embodiments (hereinafter, the noted processes and/or methods).

Processor 902 is electrically coupled to computer-readable storage medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable storage medium 904 are capable of connecting to external elements via network 914. Processor 902 is configured to execute computer program code 906 encoded in computer-readable storage medium 904 in order to cause system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable storage medium 904 is an electronic, magnetic, optical, electromagnetic, infrared, and/or a semiconductor system (or apparatus or device). For example, computer-readable storage medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 904 includes a compact disk-read only memory (CD-ROM), a compact disk-read/write (CD-R/W), and/or a digital video disc (DVD).

In one or more embodiments, storage medium 904 stores computer program code 906 configured to cause system 900 (where such execution represents (at least in part) the EDA tool) to be usable for performing a portion or all of the noted processes and/or methods. In one or more embodiments, storage medium 904 also stores information which facilitates performing a portion or all of the noted processes and/or methods. In one or more embodiments, storage medium 904 stores library 907 of standard cells including such standard cells as disclosed herein. In one or more embodiments, storage medium 904 stores one or more layout diagrams 909 corresponding to one or more layouts disclosed herein.

EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

EDA system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 900.

System 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. EDA system 900 is configured to receive information related to a user interface (UI) through I/O interface 910. The information is stored in computer-readable medium 904 as UI 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900. In some embodiments, a layout diagram which includes standard cells is generated using a suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

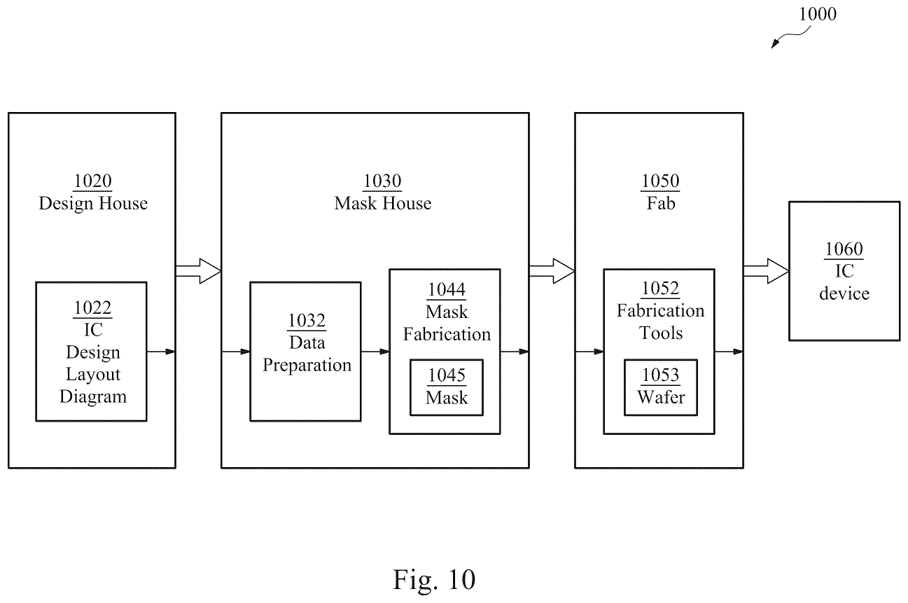

FIG. 10 is a block diagram of an integrated circuit (IC) manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (fab) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns designed for an IC device 1060. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place and route. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (RDF). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for photolithographic implementation effects during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

An aspect of the present disclosure relates to an integrated circuit device. The integrated circuit device includes tall cells having wide CFET devices therein and arranged along a first direction as a first row; short cells having narrow CFET devices therein and arranged along the first direction as a second row, the second row being adjacent to the first row, where a height of the second row having short cells is smaller a height of the first row having tall cells as measured along a second direction which is perpendicular to the first direction, and where at least three short cells consecutively arranged in the second row of short cells are absence of any self-aligned vertical interconnect; and one or more self-aligned vertical interconnects in the first row of tall cells, where each self-aligned vertical interconnect extending in a third direction is at least partially embedded into a side-recess, the third direction being perpendicular to both the first direction and the second direction, and where the side-recess has a boundary surface conformally coated with insulation materials which terminate at least one gate-conductor intersecting an active-region structure in a tall cell.

Another aspect of the present disclosure relates to an integrated circuit device. The integrated circuit device includes a substrate; a first-type wide active-region structure and a second-type wide active-region structure stacked with each other at a front side of the substrate, where each of the first-type wide active-region structure and the second-type wide active-region structure extends in a first direction; a first vertical interconnect embedded at least partially in a first side-recess and a second vertical interconnect embedded at least partially in a second side-recess while extending in a direction perpendicular to a surface of the substrate, where each side-recess has a boundary surface conformally coated with insulation materials which terminates one or more gate-conductors intersecting the first-type wide active-region structure or the second-type wide active-region structure, where the first vertical interconnect and the second vertical interconnect are separated from each other along the first direction by a first distance; and a first-type narrow active-region structure and a second-type narrow active-region structure stacked with each other at the front side of the substrate, where each of the first-type narrow active-region structure and the second-type narrow active-region structure extends in the first direction with a uniform width for a range longer than the first distance.

Still another aspect of the present disclosure relates to a method. The method includes fabricating a first-type wide active-region structure and a first-type narrow active-region structure extending in a first direction. The method also includes fabricating lower gate-conductors each intersecting one of the first-type wide active-region structure and the first-type narrow active-region structure. The method also includes fabricating a second-type wide active-region structure atop the first-type wide active-region structure and a second-type narrow active-region structure atop the first-type narrow active-region structure. The method also includes fabricating upper gate-conductors each intersecting one of the second-type wide active-region structure and the second-type narrow active-region structure. The method also includes etching the first-type wide active-region structure and the second-type wide active-region structure to form a first side-recess and a second side-recess which are separated from each other along the first direction by a first distance, while maintaining each of the first-type narrow active-region structure and the second-type narrow active-region structure at a uniform width for a range longer than the first distance. The method also includes trimming and terminating each of the lower gate-conductors and the upper gate-conductors adjacent to the first side-recess or the second side-recess at a boundary surface of the first side-recess or the second side-recess. The method also includes depositing conformally coated insulation materials onto boundary surfaces of the first side-recess and the second side-recess. The method also includes depositing metallic materials into empty spaces which are bounded by the insulation materials on the boundary surfaces of the first side-recess and the second side-recess, and filling the empty spaces with the metallic materials, where forming a first vertical interconnect embedded at least partially in the first side-recess and a second vertical interconnect embedded at least partially in the second side-recess.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1. An integrated circuit device comprising:
tall cells having wide CFET devices (“complementary field effect transistor” devices) therein and arranged along a first direction as a first row;
short cells having narrow CFET devices therein and arranged along the first direction as a second row, the second row being adjacent to the first row, wherein a height of the second row having short cells is smaller a height of the first row having tall cells as measured along a second direction which is perpendicular to the first direction, and wherein at least three short cells consecutively arranged in the second row of short cells are absence of any self-aligned vertical interconnect; and
one or more self-aligned vertical interconnects in the first row of tall cells, wherein each of the one or more self-aligned vertical interconnects extending in a third direction is at least partially embedded into a side-recess adjacent to an active-region structure in a tall cell of the tall cells, the third direction being perpendicular to both the first direction and the second direction, and wherein the side-recess has a boundary surface conformally coated with insulation materials which terminate at least one gate-conductor intersecting the active-region structure.

2. The integrated circuit device of claim 1, comprising:
a first-type wide active-region structure and a second-type wide active-region structure stacked with each other and extending in the first direction, wherein each of the wide CFET devices comprises a first-type wide transistor in the first-type wide active-region structure and a second-type wide transistor in the second-type wide active-region structure; and
a first-type narrow active-region structure and a second-type narrow active-region structure stacked with each other and extending in the first direction, wherein each of the narrow CFET devices comprises a first-type narrow transistor in the first-type narrow active-region structure and a second-type narrow transistor in the second-type narrow active-region structure.

3. The integrated circuit device of claim 1, wherein all of the short cells in the second row of short cells are absence of any self-aligned vertical interconnect.

4. The integrated circuit device of claim 1, wherein each self-aligned vertical interconnect connects an upper-layer conducting line with a lower-layer conducting line, and wherein the upper-layer conducting line is in an upper conductor layer above all active-region structures and the lower-layer conducting line is in a lower conductor layer below all active-region structures.

5. The integrated circuit device of claim 4, wherein each self-aligned vertical interconnect is configured to receive a supply voltage through the upper-layer conducting line or through the lower-layer conducting line.

6. The integrated circuit device of claim 1, comprising:
a first group of conducting lines extending in the first direction and overlapping with the first row of tall cells; and
a second group of conducting lines extending in the first direction and overlapping with the second row of short cells, wherein the first group has more conducting lines than the second group.

7. An integrated circuit device comprising:
a substrate;
a first-type wide active-region structure and a second-type wide active-region structure stacked with each other at a front side of the substrate, wherein each of the first-type wide active-region structure and the second-type wide active-region structure extends in a first direction;
a first vertical interconnect embedded at least partially in a first side-recess and a second vertical interconnect embedded at least partially a second side-recess while extending in a direction perpendicular to a surface of the substrate, wherein each side-recess has a boundary surface conformally coated with insulation materials which terminates one or more gate-conductors intersecting the first-type wide active-region structure or the second-type wide active-region structure, wherein the first vertical interconnect and the second vertical interconnect are separated from each other along the first direction by a first distance; and
a first-type narrow active-region structure and a second-type narrow active-region structure stacked with each other at the front side of the substrate, wherein each of the first-type narrow active-region structure and the second-type narrow active-region structure extends in the first direction with a uniform width for a range longer than the first distance.

8. The integrated circuit device of claim 7, wherein the boundary surface of each side-recess terminates one or more gate-conductors intersecting the first-type wide active-region structure or the second-type wide active-region structure.

9. The integrated circuit device of claim 7, wherein each of the first side-recess and the second side-recess is at least partially embedded into the first-type wide active-region structure and the second-type wide active-region structure.

10. The integrated circuit device of claim 7, wherein each of the first-type wide active-region structure and the second-type wide active-region structure has a uniform width.

11. The integrated circuit device of claim 7, wherein each of the first-type wide active-region structure and the second-type wide active-region structure has a first reduced width in a first segment adjacent to a first side-recess, a second reduced width in a second segment adjacent to a second side-recess, and a wide width in a third segment between the first segment and the second segment.

12. The integrated circuit device of claim 7, further comprising:
upper-layer conducting lines in an upper conductor layer above all active-region structures; and
lower-layer conducting lines in a lower conductor layer below all active-region structures, and wherein each of the first vertical interconnect and the second vertical interconnect connects one of the upper-layer conducting lines with one of the lower-layer conducting lines.

13. The integrated circuit device of claim 12, wherein each of the first vertical interconnect and the second vertical interconnect is configured to receive a supply voltage through an upper-layer conducting line or through a lower-layer conducting line.

14. The integrated circuit device of claim 7, further comprising:
a power rail extending in the first direction, and wherein a region separating the power rail from the first-type narrow active-region structure and the second-type narrow active-region structure is absence of a vertical interconnect for a range measured along the first direction which is longer than the first distance.

15. The integrated circuit device of claim 7, wherein a width of the first-type wide active-region structure is larger than a width of the first-type narrow active-region structure, and a width of the second-type wide active-region structure is larger than a width of the second-type narrow active-region structure.

16. The integrated circuit device of claim 7, wherein each vertical interconnects is a self-aligned vertical interconnect.

17. The integrated circuit device of claim 7, comprising:
a row of tall cells having first-type transistors in the first-type wide active-region structure and having second-type transistors in the second-type wide active-region structure; and
a row of short cells having first-type transistors in the first-type narrow active-region structure and having second-type transistors in the second-type narrow active-region structure, wherein each short cell is absence of any self-aligned vertical interconnect.

18. The integrated circuit device of claim 17, comprising:
a first group of conducting lines extending in the first direction and overlapping with the row of tall cells; and
a second group of conducting lines extending in the first direction and overlapping with the row of short cells, wherein the first group has more conducting lines than the second group.

19. A method comprising:
fabricating a first-type wide active-region structure and a first-type narrow active-region structure extending in a first direction;
fabricating lower gate-conductors each intersecting one of the first-type wide active-region structure and the first-type narrow active-region structure;
fabricating a second-type wide active-region structure atop the first-type wide active-region structure and a second-type narrow active-region structure atop the first-type narrow active-region structure;
fabricating upper gate-conductors each intersecting one of the second-type wide active-region structure and the second-type narrow active-region structure;
etching the first-type wide active-region structure and the second-type wide active-region structure to form a first side-recess and a second side-recess which are separated from each other along the first direction by a first distance, while maintaining each of the first-type narrow active-region structure and the second-type narrow active-region structure at a uniform width for a range longer than the first distance;
trimming and terminating each of the lower gate-conductors and the upper gate-conductors adjacent to the first side-recess or the second side-recess at a boundary surface of the first side-recess or the second side-recess;
depositing conformally coated insulation materials onto boundary surfaces of the first side-recess and the second side-recess; and
depositing metallic materials into empty spaces which are bounded by the insulation materials on the boundary surfaces of the first side-recess and the second side-recess, and filling the empty spaces with the metallic materials, whereby forming a first vertical interconnect embedded at least partially in the first side-recess and a second vertical interconnect embedded at least partially in the second side-recess.

20. The method of claim 19, further comprising:
fabricating lower-layer conducting lines in a lower conductor layer below all active-region structures;
fabricating upper-layer conducting lines in an upper conductor layer above all active-region structures; and
connecting the first vertical interconnect conductively between a first upper-layer conducting line and a first lower-layer conducting line, and connecting the second vertical interconnect conductively between a second upper-layer conducting line and a second lower-layer conducting line.
